(19) United States
(12) Patent Application Publication
(10) Pub. No.: US 2026/0082910 A1
(43) Pub. Date: Mar. 19, 2026

(54) SEMICONDUCTOR PACKAGE

(71) Applicant: Samsung Electronics Co., Ltd., Suwon-si (KR)

(72) Inventor: Minjung Kim, Suwon-si (KR)

(73) Assignee: Samsung Electronics Co., Ltd., Suwon-si (KR)

(21) Appl. No.: 19/059,561

(22) Filed: Feb. 21, 2025

(30) Foreign Application Priority Data
Sep. 13, 2024 (KR) 10-2024-0126027

(51) Int. Cl. H01L 23/373; H01L 23/00; H01L 23/29; H01L 23/31; H01L 23/498; H01L 25/11

(52) U.S. Cl. CPC H10W 40/251; H10W 74/121; H10W 90/00; H10W 74/473; H10W 90/22; H10W 90/288; H10W 90/701; H10W 90/722; H10W 90/724

(57) ABSTRACT

A semiconductor package may include a first redistribution substrate, a semiconductor chip on the first redistribution substrate, a mold layer provided on the first redistribution substrate to cover the semiconductor chip, a capping layer on the mold layer, a conductive post horizontally spaced apart from the semiconductor chip to penetrate the capping layer and the mold layer, and a second redistribution substrate provided on the capping layer and electrically connected to the conductive post. A thermal conductivity of the mold layer may be higher than a thermal conductivity of the capping layer.

### CROSS-REFERENCE TO RELATED APPLICATIONS

This present application claims priority to and the benefit under 35 U.S. C. § 119(a)-(d) of Korean Patent Application No. 10-2024-0126027, filed on Sep. 13, 2024, in the Korean Intellectual Property Office, the entire disclosure of which is incorporated herein by reference.

### BACKGROUND

The present disclosure relates to a semiconductor package.

Recently, demand for portable electronic devices has been rapidly increasing in the market, and thus, it is necessary to reduce sizes and weights of electronic components constituting the portable electronic devices. For this, it is necessary to develop packaging technologies capable of reducing a size and a weight of each component and of integrating a plurality of individual components in a single package.

### SUMMARY

Some embodiments of the inventive concept provide a semiconductor package with improved heat dissipation efficiency and reliability and a method of fabricating the same.

According to some embodiments of the inventive concept, a semiconductor package may include a first redistribution substrate, a semiconductor chip on the first redistribution substrate, a mold layer provided on the first redistribution substrate to cover the semiconductor chip, a capping layer on the mold layer, a conductive post horizontally spaced apart from the semiconductor chip to penetrate the capping layer and the mold layer, and a second redistribution substrate provided on the capping layer and electrically connected to the conductive post. A thermal conductivity of the mold layer may be higher than a thermal conductivity of the capping layer.

According to some embodiments of the inventive concept, a semiconductor package may include a first redistribution substrate, a semiconductor chip on the first redistribution substrate, a mold layer provided on the first redistribution substrate to cover the semiconductor chip, a capping layer on the mold layer, a conductive post horizontally spaced apart from the semiconductor chip to penetrate the capping layer and the mold layer, and a second redistribution substrate provided on the capping layer and electrically connected to the conductive post. Each of the mold and capping layers may include an epoxy resin and a first element. A first concentration of the first element in the mold layer may be different from a second concentration of the first element in the capping layer, and the first element may include aluminum (Al) or silicon (Si).

According to some embodiments of the inventive concept, a semiconductor package may include a first redistribution substrate including first insulating layers and first redistribution patterns at least partially penetrating the first insulating layers, a semiconductor chip on the first redistribution substrate, a mold layer provided on the first redistribution substrate to cover the semiconductor chip, a capping layer on the mold layer, a conductive post horizontally spaced apart from the semiconductor chip to penetrate the capping layer and the mold layer, a second redistribution substrate provided on the capping layer, the second redistribution substrate including second insulating layers and second redistribution patterns at least partially penetrating the second insulating layers, and an outer coupling terminal on a bottom surface of the first redistribution substrate. The first redistribution patterns, the conductive post, and the second redistribution patterns may be electrically connected to each other, and a thermal conductivity of the mold layer may be higher than a thermal conductivity of the capping layer.

According to some embodiments, a method of manufacturing a semiconductor package may include: obtaining a preliminary semiconductor package including: a first carrier substrate, a first redistribution substrate on the first carrier substrate, at least one conductive post extending vertically from the first carrier substrate, and a semiconductor chip on the first redistribution substrate; obtaining a semiconductor manufacturing apparatus including a capping film and a mold layer on the capping film; inserting the preliminary semiconductor package into the semiconductor manufacturing apparatus such that the at least one conductive post penetrates the capping film and the mold layer; forming a capping layer, wherein forming the capping layer comprises performing a grinding process on the capping film; and forming a second redistribution substrate on the capping layer, wherein the second redistribution substrate is electrically connected to the at least one conductive post.

In some embodiments, a thermal conductivity of the mold layer may be higher than a thermal conductivity of the capping layer.

In some embodiments, after inserting the preliminary semiconductor package into the semiconductor manufacturing apparatus, the capping layer may be spaced apart vertically from the semiconductor chip.

In some embodiments, performing the grinding process on the capping film may include removing a portion of the capping film such that a top surface of the capping film is coplanar with a top surface of the at least one conductive post.

### BRIEF DESCRIPTION OF THE DRAWINGS

FIG. 1 is a plan view illustrating a semiconductor package according to some embodiments of the inventive concept.

FIG. 2 is a sectional view taken along a line A-A′ of FIG. 1.

FIGS. 3A and 3B are sectional views illustrating a semiconductor package according to some embodiments of the inventive concept.

FIGS. 4A-4B and 5A-5E are sectional views illustrating a method of fabricating a semiconductor package, according to some embodiments of the inventive concept.

FIGS. 6A and 6B are a plan view and a sectional view respectively illustrating a portion of a process of fabricating a semiconductor package according to some embodiments of the inventive concept.

### DETAILED DESCRIPTION

Example embodiments of the inventive concepts will now be described more fully with reference to the accompanying drawings, in which example embodiments are shown.

As described herein, for a semiconductor package, it may be desirable to have packaging technologies capable of reducing a size and a weight of each component and of integrating a plurality of individual components in a single package. Especially for a semiconductor package in which a plurality of components are provided, it is necessary to improve warpage, heat dissipation, and electric characteristics of the semiconductor package, in addition to the reducing of the size of the package.

Described herein are semiconductor packages that may have improved characteristics including heat dissipation and reduction of warpage. In conventional manufacturing of semiconductor packages, an epoxy mold compound, including a high-k material (e.g., SiO₂ or Al₂O₃) may be used as a mold layer. The mold layer may encapsulate a semiconductor chip. During fabrication of the semiconductor package, an undulation issue can occur in a process of grinding the mold layer. The inventors have appreciated that such undulation can be avoided by forming an additional encapsulation layer on the mold layer, the additional encapsulation layer being referred to as a capping layer. With the additional encapsulation layer, a step of grinding the mold layer can be omitted during fabrication in favor of grinding the capping layer. In some embodiments, the conventional epoxy mold compound may be used as the additional encapsulation layer without a filler.

However, in some examples, the additional encapsulation layer may have weaker heat dissipative properties, thereby degrading the thermal properties of the semiconductor package. Therefore, the inventors have developed semiconductor packages incorporating a mold layer in direct contact with a semiconductor chip and an additional encapsulation layer that is not in direct contact with the semiconductor chip (e.g., spaced apart from the semiconductor chip). Moreover, the inventors have recognized that when the mold layer is in contact with a top surface of the semiconductor chip, the mold layer can be formed having an increased thermal conductivity to enhance the thermal properties of the semiconductor package. In other examples, a metal pattern, having good heat dissipation ability, can be formed in contact with the top surface of the semiconductor chip. As described herein, a semiconductor package may incorporate varying thermal properties of layers to improve the heat dissipation ability of the semiconductor package.

According to some embodiments, a semiconductor package with improved heat dissipation efficiency and reliability may be provided.

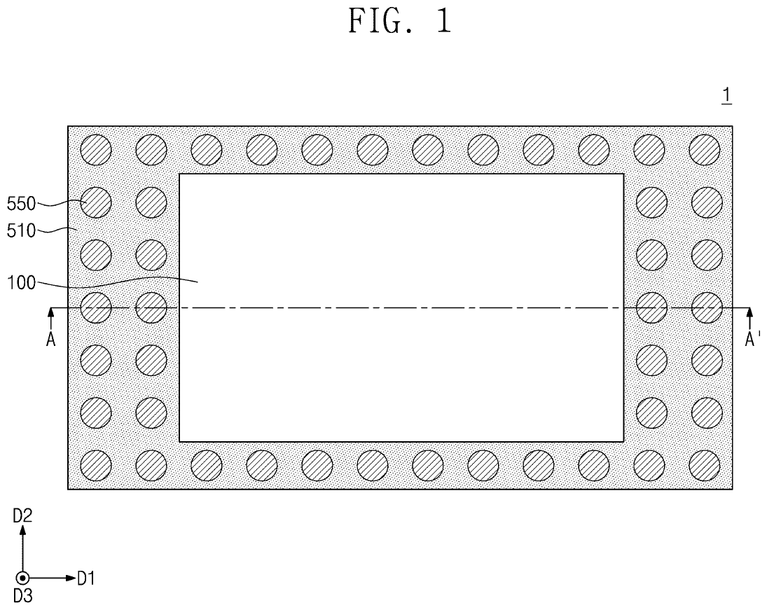

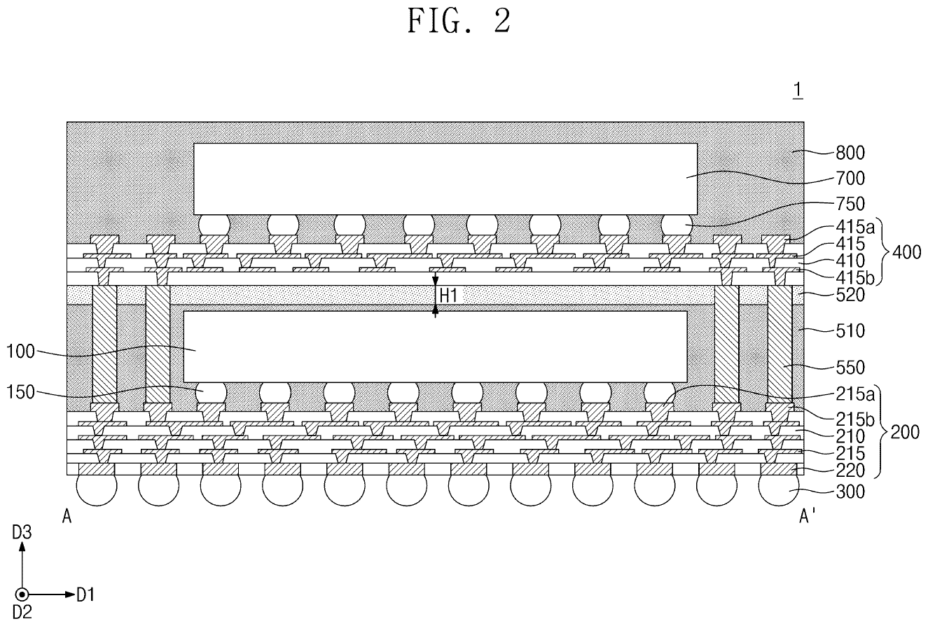

FIG. 1 is a plan view illustrating a semiconductor package according to some embodiments of the inventive concept. FIG. 2 is a sectional view taken along a line A-A′ of FIG. 1.

Referring to FIGS. 1 and 2, a semiconductor package 1 according to some embodiments of the inventive concept may include a first redistribution substrate 200, a first semiconductor chip 100, a mold layer 510, a capping layer 520, and a conductive post 550.

The first redistribution substrate 200 may include a plurality of first insulating layers 210 and a plurality of first redistribution patterns 215, which are sequentially stacked. In the present specification, a first direction D1 may be defined as a direction that is parallel to a bottom surface of the first redistribution substrate 200. A second direction D2 may be defined as a direction that is parallel to the bottom surface of the first redistribution substrate 200 and is perpendicular to the first direction D1. A third direction D3 may be defined as a direction that is perpendicular to the bottom surface of the first redistribution substrate 200.

The first insulating layers 210 may include an organic material (e.g., a photoimageable dielectric (PID) material). The PID material may be at least one of one or more polymers. The PID material may include at least one of photoimageable polyimide, polybenzoxazole, phenol-based polymers, or benzocyclobutene-based polymers. Interfaces between the first insulating layers 210 are illustrated in FIG. 2, but the inventive concept is not limited to this example. In another embodiment, an interface between adjacent ones of the first insulating layers 210 may not be observable or visible.

The first redistribution patterns 215 may be provided in the first insulating layers 210. Each of the first redistribution patterns 215 may be provided to penetrate at least a portion of the first insulating layer 210. Each of the first redistribution patterns 215 may have a first via portion and a first wire portion, which are connected to form a single object. The first wire portion may be a pattern, which is used for the horizontal interconnection in the first redistribution substrate 200. The first via portion may be a portion, which is provided in the first insulating layers 210 and is used to vertically connect the first redistribution patterns 215 to each other. The first wire portion may be provided on the first via portion. The first wire portion may be connected to the first via portion, without an interface therebetween. The first wire portion of the first redistribution pattern 215 may be located on a top surface of the first insulating layer 210. The first via portion of the first redistribution pattern 215 may penetrate the first insulating layer 210 and may be connected to the first wire portion of another first redistribution pattern 215 therebelow. The first via portion may have a tapered structure having an increasing horizontal width in an upward direction. For example, the horizontal width of the first via portion may increase as a distance to the first semiconductor chip 100 decreases. The first redistribution patterns 215 may include a conductive material. For example, the first redistribution patterns 215 may include copper (Cu).

Although not shown, seed patterns may be disposed on bottom surfaces of the first redistribution patterns 215. For example, each of the seed patterns may cover bottom and side surfaces of the first via portion and a bottom surface of the first wire portion in a corresponding one of the first redistribution patterns 215. The seed patterns may include a material different from the first redistribution patterns 215. For example, the seed patterns may include copper (Cu), titanium (Ti), or alloys thereof. In an embodiment, the first redistribution pattern 215 may further include a barrier layer preventing a material diffusion issue in the first redistribution pattern 215. The barrier layer may include titanium nitride (TiN) or tantalum nitride (TaN).

The first redistribution patterns 215 may include first redistribution pads 215a and 215b. For example, the first redistribution pads 215a and 215b may be some of the first redistribution patterns 215 placed at the highest level of the first redistribution substrate 200. The first redistribution pads 215a and 215b may have top surfaces protruding to a level higher than the highest one of the first insulating layers 210.

Under-bump patterns 220 may be provided on the bottom surface of the first redistribution substrate 200. The under-bump patterns 220 may be spaced apart from each other in the first direction D1. The under-bump patterns 220 may be electrically connected to the first redistribution patterns 215. For example, the under-bump patterns 220 may be directly connected to the lowermost ones of the first redistribution patterns 215. The under-bump patterns 220 may be electrically connected to the first redistribution pads 215a and 215b through the first redistribution patterns 215. The under-bump patterns 220 may include a conductive material. For example, the under-bump patterns 220 may include copper (Cu).

Outer coupling terminals 300 may be provided on bottom surfaces of the under-bump patterns 220, respectively. The outer coupling terminals 300 may be spaced apart from each other in the first direction D1. The outer coupling terminals 300 may include a solder material. For example, the outer coupling terminals 300 may include at least one of tin (Sn), bismuth (Bi), lead (Pb), silver (Ag), or alloys thereof.

First connection terminals 150 may be provided on the first redistribution substrate 200. The first connection terminals 150 may be directly connected to the first redistribution pads 215a and may be electrically connected to the first redistribution pattern 215. The first connection terminals 150 may be spaced apart from each other in the first direction D1 and may be used to connect the first redistribution substrate 200 to the first semiconductor chip 100. The first connection terminals 150 may include a solder material. For example, the first connection terminals 150 may include tin (Sn), bismuth (Bi), lead (Pb), silver (Ag), or alloys thereof.

The first semiconductor chip 100 may be disposed on a top surface of the first redistribution substrate 200. The first semiconductor chip 100 may include chip pads (not shown) disposed on a bottom surface thereof. In an embodiment, the first semiconductor chip 100 may be a memory chip or a logic chip. Here, the memory chip may be, for example, volatile memory chips (e.g., dynamic random access memory (DRAM) and static random access memory (SRAM) chips) or nonvolatile memory chips (e.g., phase-change random access memory (PRAM), magnetoresistive random access memory (MRAM), ferroelectric random access memory (FeRAM), and resistive random access memory (RRAM) chips). The logic chip may be, for example, micro-processors (e.g., a central processing unit (CPU), a graphics processing unit (GPU), or an application processor (AP)), analog devices, or digital signal processors.

The mold layer 510 may be disposed on the top surface of the first redistribution substrate 200. The mold layer 510 on the first redistribution substrate 200 may cover the first semiconductor chip 100. For example, the mold layer 510 may cover a top surface and side surfaces of the first semiconductor chip 100. In some embodiments, the mold layer may at least partially encapsulate the semiconductor chip. That is, the mold layer may encapsulate at least a side surface and, optionally, a top surface of the semiconductor chip. The mold layer may encapsulate each side surface and the top surface of the semiconductor chip in some embodiments.

The mold layer 510 may include an epoxy molding compound. In an embodiment, the mold layer 510 may include an epoxy resin and a filler and may further include an oxide material that is based on a first element. In another embodiment, the mold layer 510 may include a silicon resin and a filler and may further include an oxide material that is based on a first element. The first element may be silicon (Si) or aluminum (Al). The filler may include an inorganic filler or an organic filler and may further include carbon black.

In other words, the mold layer 510 according to an embodiment of the inventive concept may include the oxide material containing the first element. For example, the mold layer 510 may include silicon oxide and/or aluminum oxide in a high content. The silicon oxide and the aluminum oxide may correspond to a relatively high-k material in the mold layer 510. In the case where the mold layer 510 includes the silicon oxide and/or the aluminum oxide in a high content, the thermal conductivity of the mold layer 510 may be increased, and the heat dissipation ability of the semiconductor package 1 may be improved. In some embodiments, the thermal conductivity of the mold layer 510 may range from 2.5 W/m·K to 5.0 W/m·K.

The capping layer 520 may be disposed on the mold layer 510. The capping layer 520 may cover a top surface of the mold layer 510 and may be spaced apart from the first semiconductor chip 100. In an embodiment, a thickness H1 of the capping layer 520 may range from 10 μm to 500 μm. The thickness H1 of the capping layer 520 may mean a length of the capping layer 520 in the third direction D3.

In an embodiment, the capping layer 520 may include an epoxy resin (or silicon resin). In the case where the capping layer 520 includes the epoxy resin, the capping layer 520 may not include a filler, or the content of the filler may be lower in the capping layer 520 than in the mold layer 510. Furthermore, the capping layer 520 may not include the oxide material containing the first element. In other words, the capping layer 520 may not contain the first element, or the content of the first element may be lower in the capping layer 520 than in the mold layer 510. That is, a concentration of the first element in the mold layer 510 may be higher/greater than a concentration of the first element in the capping layer 520. Furthermore, since the capping layer 520 contains the first element in a lowered content, the thermal conductivity of the capping layer 520 may be different from the thermal conductivity of the mold layer 510. As an example, the thermal conductivity of the capping layer 520 may be smaller than the thermal conductivity of the mold layer 510.

The conductive posts 550 may be disposed on the first redistribution substrate 200. Each of the conductive posts 550 may penetrate the mold layer 510 and the capping layer 520. For example, a portion of the conductive post 550 may be inserted into the capping layer 520. The conductive posts 550 may be spaced apart from each other in the first and second directions D1 and D2. The conductive posts may be horizontally spaced apart from the semiconductor chip. The conductive posts 550 may be disposed to enclose the first semiconductor chip 100, when viewed in a plan view, but the inventive concept is not limited to this example. The conductive posts 550 may electrically connect the first redistribution substrate 200 to a second redistribution substrate 400, which will be described below. Bottom surfaces of the conductive posts 550 may be directly connected to the first redistribution pads 215b. Top surfaces of the conductive posts 550 may be coplanar with a top surface of the capping layer 520.

A second redistribution substrate 400 may be disposed on the capping layer 520. The second redistribution substrate 400 may include a plurality of second insulating layers 410 and a plurality of second redistribution patterns 415, which may be sequentially stacked. The second insulating layers 410 may include an organic material (e.g., a photoimageable dielectric (PID) material). The conductive posts may be electrically connected to the second redistribution substrate as well as the first redistribution substrate.

The second redistribution patterns 415 may be provided in the second insulating layers 410. Each of the second redistribution patterns 415 may penetrate at least a portion of the second insulating layer 410. At least one of the second redistribution patterns 415 may include a second via portion and a second wire portion, which are connected to form a single object. The second wire portion may be a pattern, which is used for the horizontal interconnection in the second redistribution substrate 400. The second via portion may be a portion, which is provided in the second insulating layers 410 and is used to vertically connect the second redistribution patterns 415 to each other. The second wire portion may be provided on the second via portion. The second wire portion may be connected to the second via portion, without an interface therebetween. The second via portion may have a tapered structure having an increasing horizontal width in an upward direction. For example, the horizontal width of the second via portion may decrease as a distance to the first semiconductor chip 100 decreases.

The second redistribution patterns 415 may include second redistribution pads 415a. For example, the second redistribution pads 415a may be some of the second redistribution patterns 415 placed at the highest level of the second redistribution substrate 400. The second redistribution pads 415a may have top surfaces protruding to a level higher than the highest one of the second insulating layers 410.

A second semiconductor chip 700 may be disposed on the second redistribution substrate 400. The second semiconductor chip 700 may include chip pads (not shown) provided on a bottom surface thereof. As an example, the second semiconductor chip 700 may be a memory chip or a logic chip.

Second connection terminals 750 may be provided between the second redistribution substrate 400 and the second semiconductor chip 700. The second connection terminals 750 may be directly connected to the second redistribution pads 415a and may be electrically connected to the second redistribution pattern 415. The second connection terminals 750 may be spaced apart from each other in the first direction D1 and may be used to connect the second redistribution substrate 400 to the second semiconductor chip 700. The second connection terminals 750 may include a solder material.

An upper mold layer 800 may be provided on the second redistribution substrate 400 to cover the second semiconductor chip 700. The upper mold layer 800 may include an epoxy molding compound. In an embodiment, the upper mold layer 800 may include an epoxy resin and a filler. The upper mold layer 800 may further include an oxide material, which is based on the first element, but the inventive concept is not limited to this example.

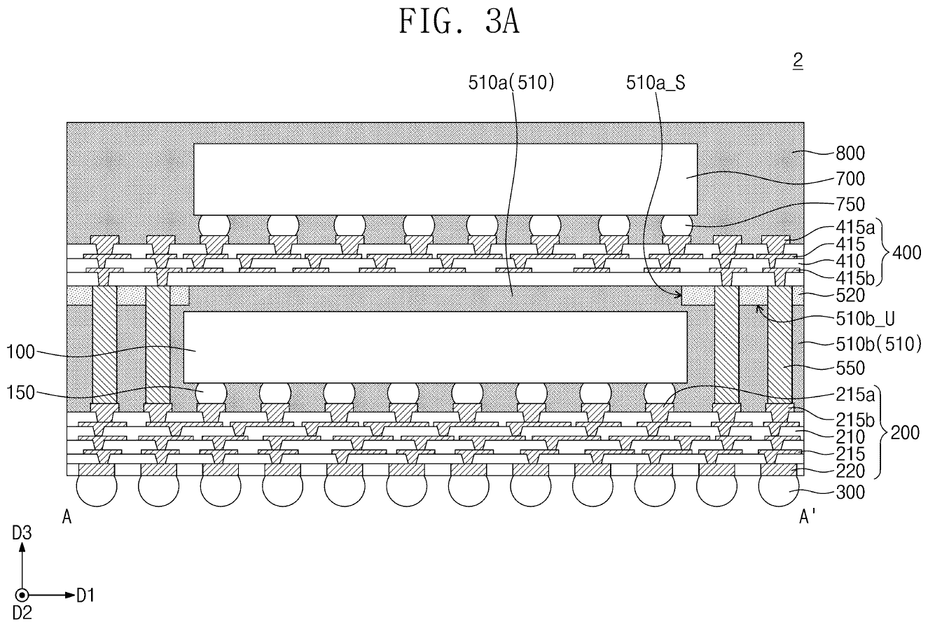

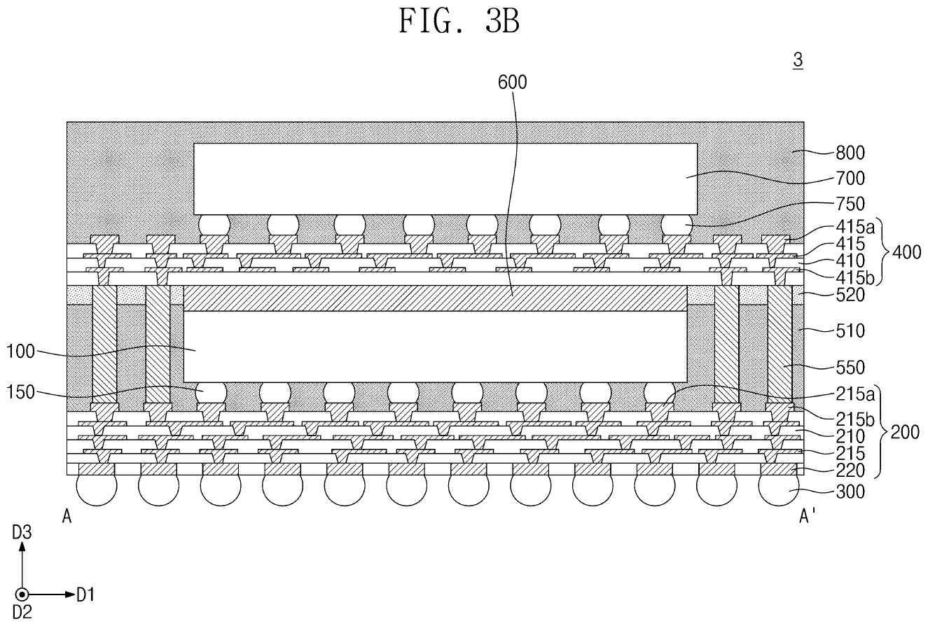

FIGS. 3A and 3B are sectional views illustrating a semiconductor package 2 and 3 according to some embodiments of the inventive concept. For concise description, an element previously described with reference to FIGS. 1 and 2 will be identified by the same reference number without repeating an overlapping description thereof, and features different from that of the previous embodiments will be described in more detail below.

Referring to FIG. 3A, the mold layer 510 may include a first portion 510a, which is provided on the first semiconductor chip 100 and is overlapped with the first semiconductor chip 100 when viewed in a plan view, and a second portion 510b, which is provided on side surfaces of the first semiconductor chip 100. The first and second portions 510a and 510b may be connected to each other without any interface therebetween. When viewed in a plan view, the mold layer 510 may have a rectangular shape, and the second portion 510b may be a portion of the mold layer 510, which is slightly recessed from the rectangular border. A top surface of the first portion 510a may be located at a level higher than a top surface 510b_U of the second portion 510b. For example, the top surface of the first portion 510a may be in contact with a bottom surface of the second redistribution substrate 400, and the top surface 510b_U of the second portion 510b may be in contact with the capping layer 520. In the present specification, the top surface of the first portion 510a may refer to a top surface of a portion of the mold layer 510 placed on the first semiconductor chip 100.

The capping layer 520 may be in contact with the first and second portions 510a and 510b of the mold layer 510. In detail, the capping layer 520 may be placed on the second portion 510b and may be in contact with the top surface 510b_U of the second portion 510b and a side surface 510a_S of the first portion 510a. The top surface of the capping layer 520 may be coplanar with the top surface of the first portion 510a.

Referring to FIG. 3B, a metal pattern 600 may be disposed between the second redistribution substrate 400 and the first semiconductor chip 100. The metal pattern 600 may cover the top surface of the first semiconductor chip 100. In other words, the metal pattern 600 and the first semiconductor chip 100 may be overlapped with each other, when viewed in a plan view. As an example, the metal pattern 600 may be a plate-shaped pattern and may have a rectangular shape, when viewed in a plan view.

Heat, which is generated from the first semiconductor chip 100, may be transferred to the second redistribution substrate 400 through the metal pattern 600 and may be exhausted to the outside. In an embodiment, the metal pattern 600 may be formed of or include copper. That is, according to an embodiment of the inventive concept, since the metal pattern 600 with good heat dissipation ability is formed on the first semiconductor chip 100, a semiconductor package 3 may have improved heat dissipation ability.

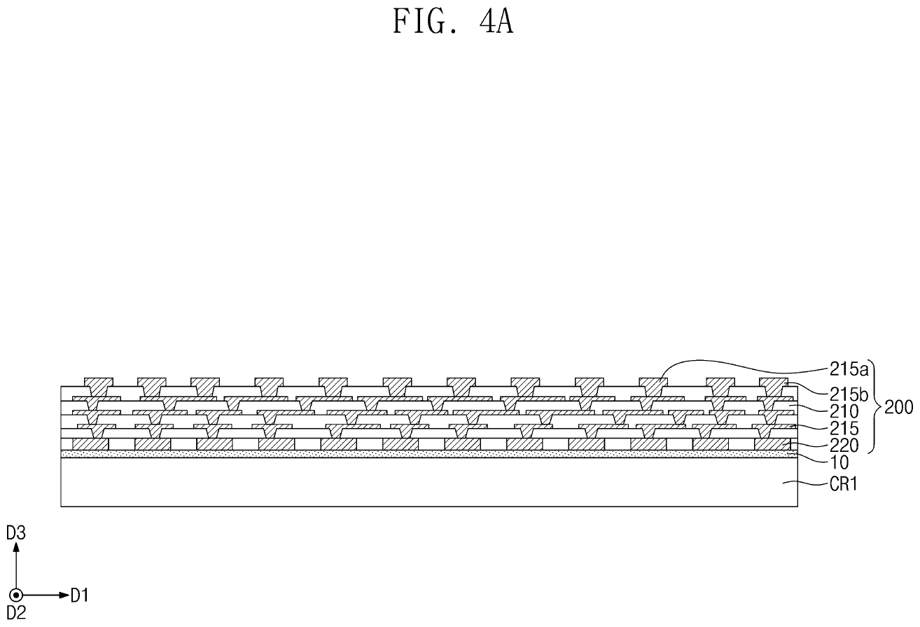

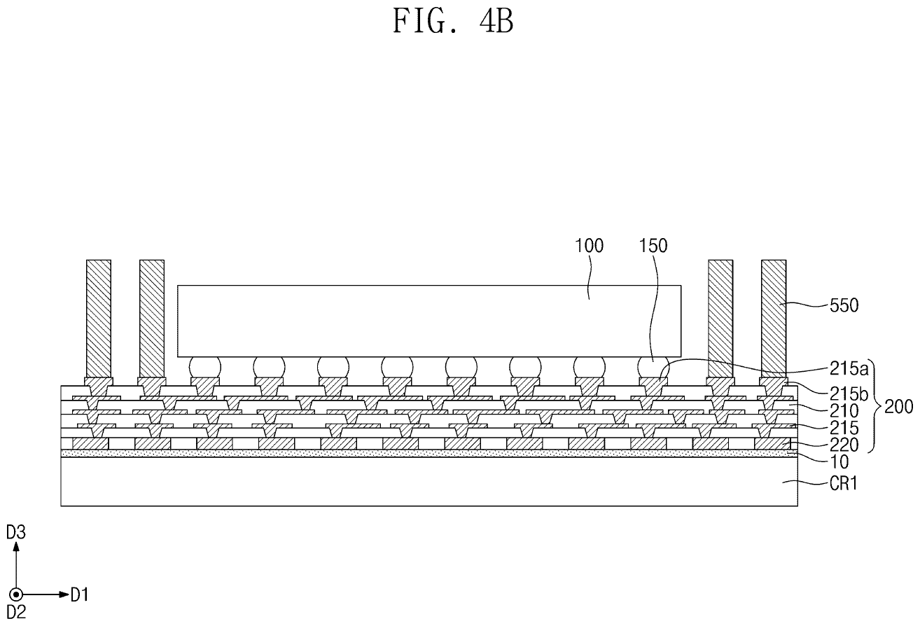

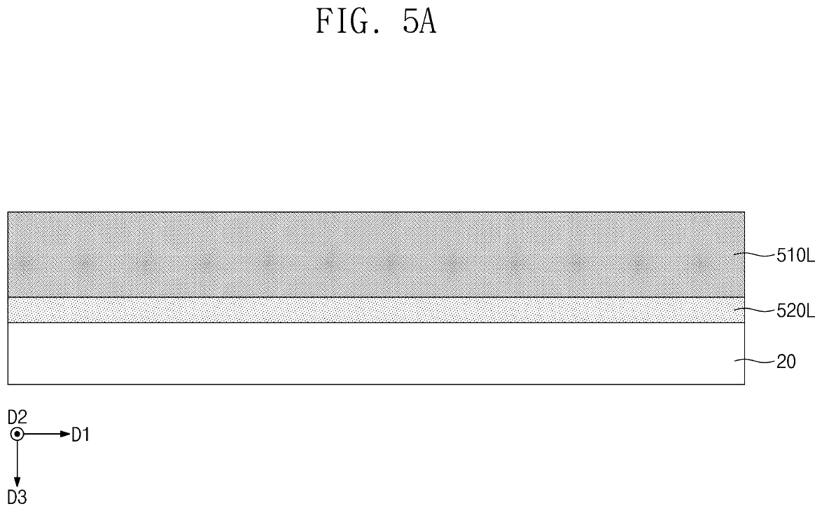

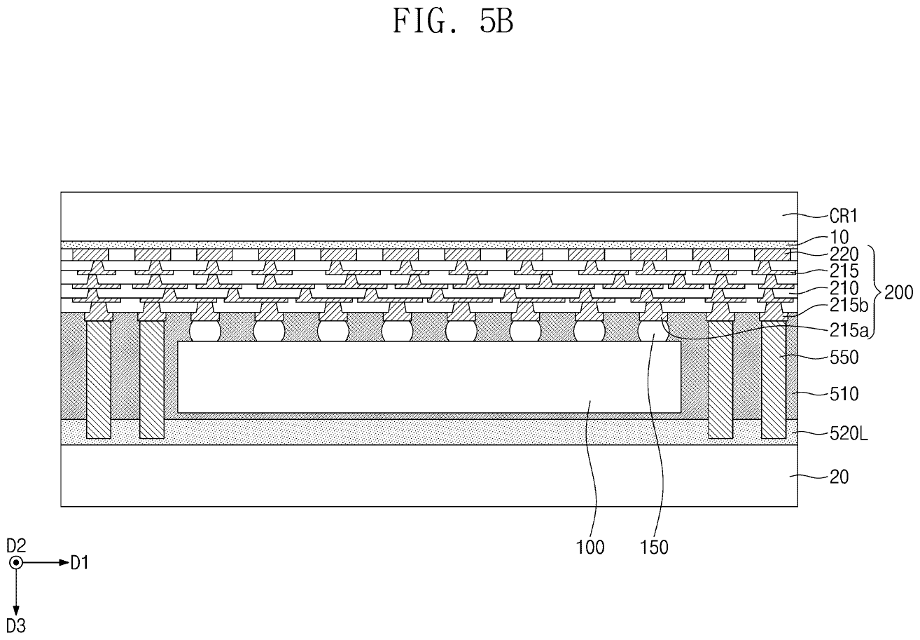

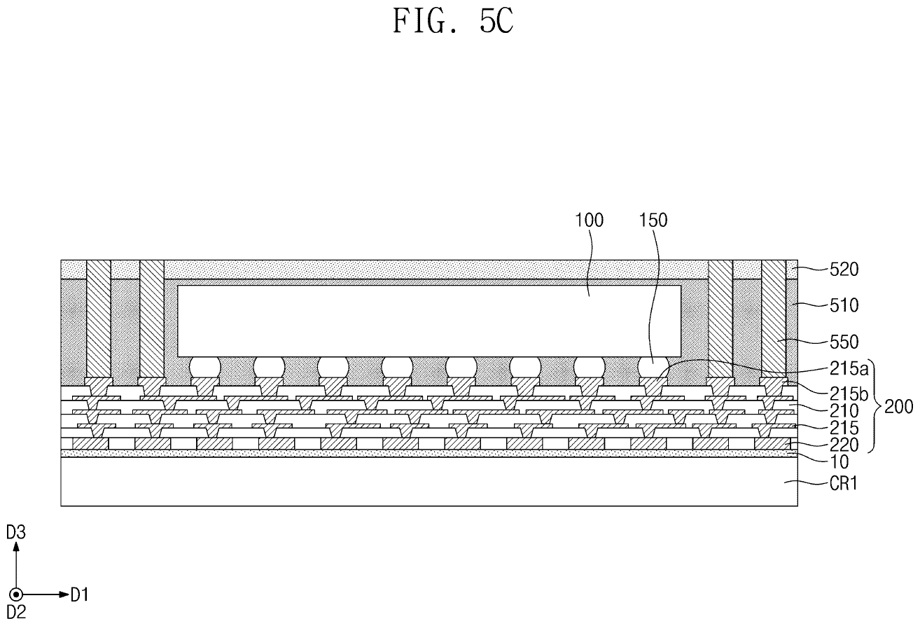

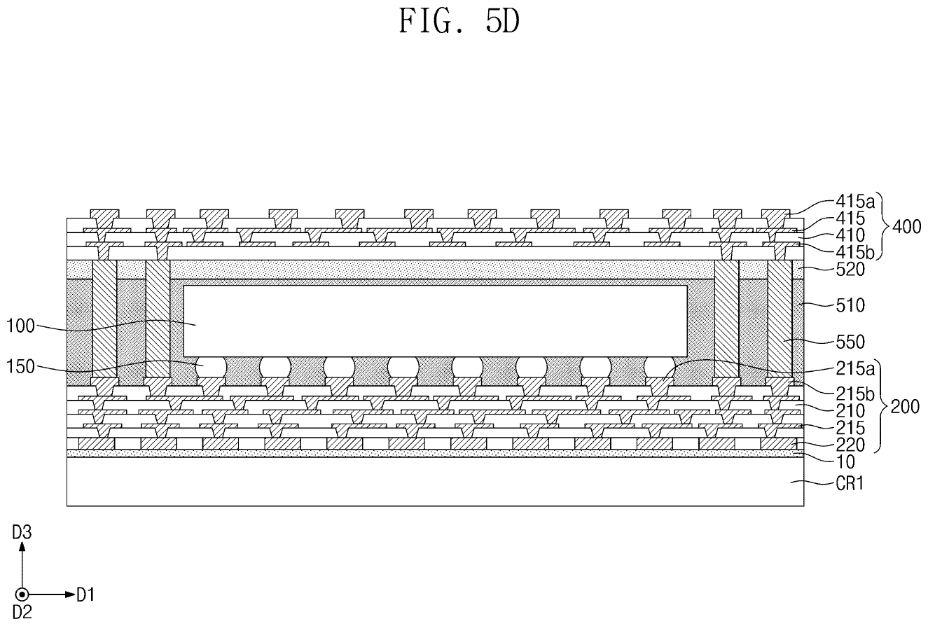

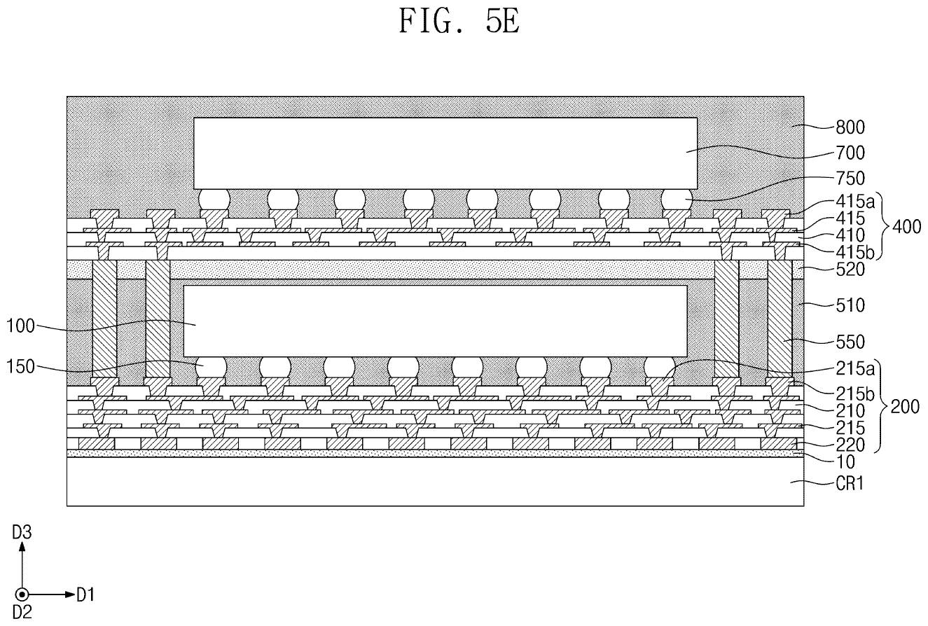

FIGS. 4A-4B and 5A-5E are sectional views illustrating a portion of fabricating a semiconductor package according to an embodiment of the inventive concept. In detail, FIGS. 4A and 4B illustrate a process of fabricating a preliminary semiconductor package, and FIGS. 5A to 5D illustrate a process of fabricating a semiconductor package from the preliminary semiconductor package.

Referring to FIG. 4A, a first carrier substrate CR1 and an adhesive member 10 on the first carrier substrate CR1 may be provided. The first carrier substrate CR1 may be an insulating substrate, which is formed of or includes glass or polymer, or a conductive substrate, which is formed of or includes a metallic material. The adhesive member 10 may include an adhesive material and/or an adhesive tape.

The first redistribution substrate 200, which includes the first insulating layers 210, the under-bump patterns 220, and the first redistribution patterns 215, may be formed on the adhesive member 10. The first redistribution substrate 200 may be formed on the first carrier substrate CR1. The formation of the first redistribution substrate 200 may include forming the first insulating layer 210 on the adhesive member 10, forming the under-bump patterns 220 to penetrate the first insulating layer 210, additionally stacking first insulating layers 210 on the first insulating layer 210, and forming the first redistribution patterns 215 to penetrate at least a portion of the first insulating layers 210.

The first insulating layers 210 may include an organic material (e.g., a photoimageable dielectric (PID) material). The formation of the under-bump patterns 220 may include patterning the first insulating layer 210 to form openings, forming a seed layer in the openings, and performing an electroplating process using the seed layer as an electrode to form a conductive pattern. The formation of the first redistribution pattern 215 may include patterning the first insulating layer 210 to form openings, forming a seed layer in the openings and on a top surface of the first insulating layer 210, forming a mask on the seed layer to define a space for a conductive pattern, performing an electroplating process using the seed layer as an electrode to form the conductive pattern, removing the mask, and patterning the seed layer using the conductive pattern as an etch mask. The first redistribution patterns 215 (or the first redistribution pads 215a and 215b) may be formed by repeating the process.

Referring to FIG. 4B, a preliminary semiconductor package may be formed by disposing the first semiconductor chip 100 and the conductive posts 550 on the first redistribution substrate 200. The first semiconductor chip 100 may be connected to the first redistribution pads 215a through the first connection terminals 150. The conductive posts 550 may be connected to the first redistribution pads 215b, which are not connected to the first semiconductor chip 100. The one or more conductive posts may extend vertically from the first carrier substrate.

Referring to FIG. 5A, a semiconductor manufacturing apparatus 20 may be provided. The semiconductor manufacturing apparatus 20 may include an apparatus, which is used to form a mold layer. As an example, the semiconductor manufacturing apparatus 20 may include an apparatus, which is configured to supply an epoxy mold compound.

A capping film 520L may be formed on the semiconductor manufacturing apparatus 20. The capping film 520L may include substantially the same material as the capping layer 520. In other words, the capping film 520L may include the epoxy resin. In an embodiment, the capping film 520L may not include a filler, and in another embodiment, the capping film 520L may further include a small amount of fillers. The capping film 520L may not include the first element, or the content of the first element may be lower in the capping film 520L than in a molding film 510L, which will be described below. The first element may be silicon (Si) or aluminum (Al).

A molding film 510L may be formed on the capping film 520L. The semiconductor manufacturing apparatus may therefore include a molding film and capping film. The molding film 510L may include substantially the same material as the mold layer 510. For example, the molding film 510L may include an epoxy resin and a filler and may further include an oxide material, which is based on the first element. The content of the filler in the molding film 510L may be higher than that in the capping film 520L. A concentration of the first element in the molding film 510L may be higher than a concentration of the first element in the capping film 520L. In addition, the thermal conductivity of the molding film 510L may range from 2.5 W/m·K to 5.0 W/m·K.

As an example, the molding film 510L may be molded by a transfer molding method. As another example, the molding film 510L may be molded by a compression molding method.

The capping film 520L and the molding film 510L may be maintained at a specific temperature (e.g., a first temperature). At the first temperature, the capping film 520L may exhibit a gel-like property. For example, the capping film 520L may have a viscous and fluidic property at the first temperature. The molding film 510L may be maintained in a liquid state at the first temperature. That is, at the first temperature, the viscosity of the molding film 510L may be lower than the viscosity of the capping film 520L.

Referring to FIGS. 5A and 5B, the preliminary semiconductor package described with reference to FIG. 4B may be inverted and then may be inserted into the molding film 510L and the capping film 520L. The first semiconductor chip 100 may be inserted into the molding film 510L, and the conductive posts 550 may penetrate the molding film 510L and may be inserted into the capping film 520L (e.g., to penetrate the capping film). As described above, the molding film 510L may be in a liquid state, and thus, the conductive posts 550 may penetrate the molding film 510L. In the case where the capping film 520L exhibits the aforementioned gel-like property or is in a viscous and fluidic state, at least a portion of the conductive post 550 may be inserted into the capping film 520L. During the insertion of the preliminary semiconductor package, the molding film 510L may be formed to be in contact with a surface of the first redistribution substrate 200 and to fill a space between the conductive posts 550 and between the conductive posts 550 and the first semiconductor chip 100.

Heat may be transferred to the molding film 510L and the capping film 520L through the semiconductor manufacturing apparatus 20. Thus, the molding film 510L and the capping film 520L may be heated to a second temperature higher than the first temperature. Chemical cross-links may be formed in the molding film 510L at the second temperature, and the molding film 510L may be hardened or cured to exhibit a gel-like property. Thus, the molding film 510L of FIG. 5A may be referred to as the mold layer 510.

The viscosity of the capping film 520L may be greater at the second temperature than at the first temperature. For example, if the temperature is increased, the viscosity of the capping film 520L may be exponentially or linearly increased.

Thereafter, the viscosities of the mold layer 510 and the capping film 520L may increase with time. After a certain amount of time, the mold layer 510 and the capping film 520L may be hardened or cured.

Referring to FIG. 5C, the semiconductor package may be detached from the semiconductor manufacturing apparatus 20 of FIG. 5B and may be inverted again. Thus, the first carrier substrate CR1 may be placed below the semiconductor package.

Next, a portion of the capping film 520L of FIG. 5B may be removed. In an embodiment, the (portion of) capping film 520L of FIG. 5B may be removed by a grinding process, and a remaining portion of the capping film 520L of FIG. 5B may be referred to as the capping layer 520. Forming the capping layer may therefore include performing a grinding process on the capping film. The top surface of the capping layer 520 may be coplanar with the top surfaces of the conductive posts 550. Therefore, performing the grinding process on the capping film can include removing a portion of the capping film such that a top surface of the capping film is coplanar with a top surface of the at least one conductive post.

The mold layer 510 may include an epoxy resin, a filler, and aluminum oxide (or silicon oxide) and may have a high thermal conductivity. Here, the aluminum oxide (or silicon oxide) may be strongly coupled with the epoxy resin. Thus, if the grinding process is performed on the mold layer 510, the coupling between the filler and the epoxy resin may be damaged. Further, the coupling between the aluminum oxide or silicon oxide and epoxy resin may be damaged. For example, in the case where the fabrication process includes a step of grinding the mold layer 510, an undulation issue may occur in the mold layer 510.

However, according to some embodiments of the inventive concept, since the semiconductor package further includes the capping layer 520, which is disposed on the mold layer 510, the grinding process may be performed on the capping layer 520, not the mold layer 510, and the grinding process on the mold layer 510 may be omitted. Since the concentration of aluminum (or silicon) is lower in the capping layer 520 than in the mold layer 510, the aforementioned phenomenon may be mitigated. Furthermore, it may be possible to prevent an abnormal contact issue of the second redistribution pattern 415b of FIG. 5D from occurring in a subsequent process. Accordingly, a semiconductor package with improved heat dissipation efficiency and reliability may be provided.

Referring to FIG. 5D, the second redistribution substrate 400 may be formed on the capping layer 520. The formation of the second redistribution substrate 400 may include forming the second insulating layer 410 on the capping layer 520 and forming the second redistribution patterns 415 to penetrate at least a portion of the second insulating layers 410.

The second insulating layers 410 may include an organic material (e.g., a photoimageable dielectric (PID) material). The formation of the second redistribution pattern 415 may include patterning the second insulating layer 410 to form openings, forming a seed layer in the openings and on a top surface of the second insulating layer 410, forming a mask on the seed layer to define a space for a conductive pattern, performing an electroplating process using the seed layer as an electrode to form the conductive pattern, removing the mask, and patterning the seed layer using the conductive pattern as an etch mask. The second redistribution patterns 415 (or the second redistribution pads 415a) may be formed by repeating the aforementioned process.

Referring to FIG. 5E, the second semiconductor chip 700 may be disposed on the second redistribution substrate 400. The second semiconductor chip 700 may be connected to the second redistribution pads 415a through the second connection terminal 750. Thereafter, the upper mold layer 800 may be disposed on the second redistribution substrate 400.

Referring back to FIG. 2, the adhesive member 10 and the first carrier substrate CR1 may be removed from the bottom surface of the first redistribution substrate 200. Next, the under-bump patterns 220 may be formed on the bottom surface of the first redistribution substrate 200.

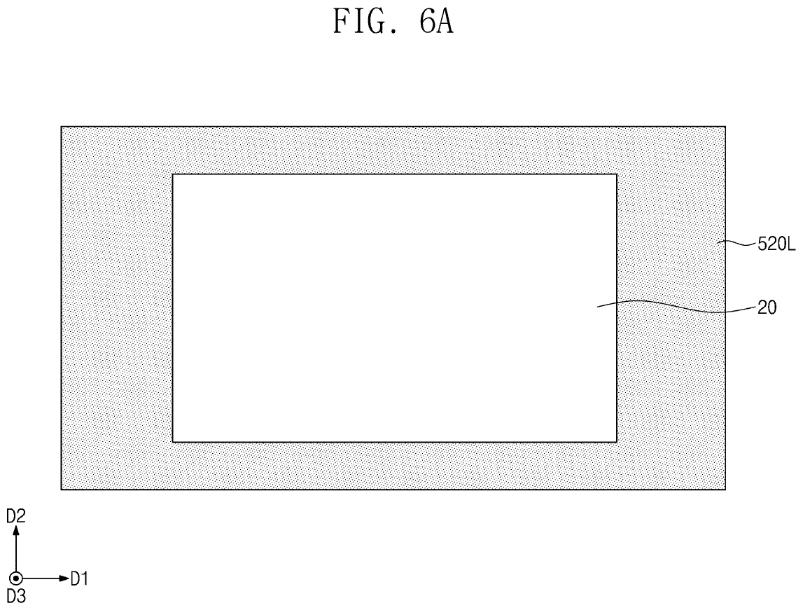

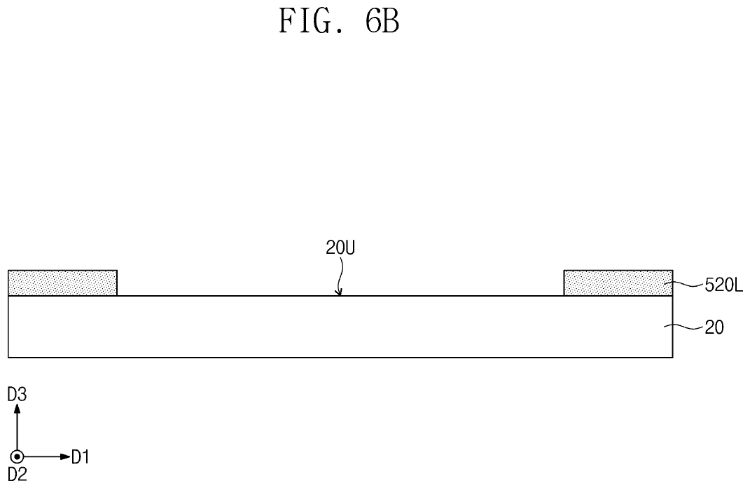

FIGS. 6A and 6B are a plan view and a sectional view respectively illustrating a portion of a process of fabricating a semiconductor package according to some embodiments of the inventive concept. The semiconductor manufacturing apparatus 20 and the capping film 520L may be configured to have substantially the same features as those in the depicted embodiment of FIG. 5A.

Referring to FIGS. 6A and 6B, the capping film 520L may be formed on the semiconductor manufacturing apparatus 20. When viewed in a plan view, the capping film 520L may be disposed to be adjacent to a border of the semiconductor manufacturing apparatus 20. For example, the capping film 520L may not cover a center region of the semiconductor manufacturing apparatus 20. A top surface 20U of the semiconductor manufacturing apparatus 20 may be exposed to the outside in the center region thereof.

In an embodiment, a process similar to that in the depicted embodiment of FIGS. 5B to 5D may be performed using the semiconductor manufacturing apparatus 20 whose top surface 20U is partially exposed to the outside. In another embodiment, the metal pattern 600 of FIG. 3B may be formed on the exposed top surface 20U of the semiconductor manufacturing apparatus 20, and the process may be performed in a manner similar to that in the embodiment of FIGS. 5B to 5D.

According to an embodiment of the inventive concept, a semiconductor package may include a mold layer, which includes an epoxy resin, a filler, and aluminum oxide (or silicon oxide) and has a high thermal conductivity. When the mold layer is ground (e.g., by grinding), the filler and the epoxy resin may be separated from each other, and this may lead to an undulation issue in the mold layer.

However, the semiconductor package may further include a capping layer, which is disposed on the mold layer, and in this case, it may be possible to omit a step of grinding the mold layer in a process of fabricating the semiconductor package. Nevertheless, it may be possible to prevent or suppress an undulation issue in the mold layer, and moreover, to prevent an upper redistribution pattern from being in abnormal contact with a conductive post in a subsequent process. Accordingly, a semiconductor package with improved heat dissipation efficiency and reliability may be provided.

As described herein, a method of manufacturing a semiconductor package may be provided. The method may include: obtaining a preliminary semiconductor package including: a first carrier substrate, a first redistribution substrate on the first carrier substrate, at least one conductive post extending vertically from the first carrier substrate, and a semiconductor chip on the first redistribution substrate; obtaining a semiconductor manufacturing apparatus including a capping film and a mold layer on the capping film; inserting the preliminary semiconductor package into the semiconductor manufacturing apparatus such that the at least one conductive post penetrates through the capping film and mold layer; forming a capping layer, wherein forming the capping layer comprises performing a grinding process on the capping film; and forming a second redistribution substrate on the capping layer, wherein the second redistribution substrate is electrically connected to the at least one conductive post. In some embodiments, the thermal conductivity of the mold layer may be higher than the thermal conductivity of the capping layer. The capping layer may be spaced apart vertically from the semiconductor chip as described herein. Performing the grinding process on the capping film may include removing a portion of the capping film such that a top surface of the capping film is coplanar with a top surface of the at least one conductive post.

While example embodiments of the inventive concept have been particularly shown and described, it will be understood by one of ordinary skill in the art that variations in form and detail may be made therein without departing from the spirit and scope of the attached claims.

What is claimed is:

1. A semiconductor package, comprising:
a first redistribution substrate;
a semiconductor chip on the first redistribution substrate;
a mold layer on the first redistribution substrate and at least partially encapsulating the semiconductor chip;
a capping layer on the mold layer;
a conductive post horizontally spaced apart from the semiconductor chip to penetrate the capping layer and the mold layer; and
a second redistribution substrate on the capping layer and electrically connected to the conductive post,
wherein a thermal conductivity of the mold layer is higher than a thermal conductivity of the capping layer.

2. The semiconductor package of claim 1, wherein:
the mold layer comprises an epoxy resin, and
the mold layer further comprises silicon oxide or aluminum oxide.

3. The semiconductor package of claim 1, wherein the mold layer covers a top surface of the semiconductor chip, and
the capping layer is spaced apart from the semiconductor chip.

4. The semiconductor package of claim 1, wherein a thickness of the capping layer ranges from 10 μm to 500 μm.

5. The semiconductor package of claim 1, wherein the thermal conductivity of the mold layer ranges from 2.5 W/m·K to 5.0 W/m·K.

6. The semiconductor package of claim 1, wherein the mold layer comprises a first portion, which is on the semiconductor chip and is overlapped with the semiconductor chip in a plan view, and a second portion, which is on a side surface of the semiconductor chip, and
wherein the capping layer is in contact with a top surface of the second portion.

7. The semiconductor package of claim 6, wherein a top surface of the capping layer is coplanar with a top surface of the first portion.

8. The semiconductor package of claim 6, wherein a top surface of the first portion is located at a level higher than the top surface of the second portion.

9. The semiconductor package of claim 1, further comprising a metal pattern between the second redistribution substrate and the semiconductor chip,
wherein the metal pattern is in contact with a top surface of the semiconductor chip.

10. The semiconductor package of claim 9, wherein the metal pattern is a plate-shaped pattern.

11. The semiconductor package of claim 1, wherein the capping layer comprises at least one of an epoxy resin and a silicon resin.

12. A semiconductor package, comprising:
a first redistribution substrate;
a semiconductor chip on the first redistribution substrate;
a mold layer on the first redistribution substrate to cover the semiconductor chip;
a capping layer on the mold layer;
a conductive post horizontally spaced apart from the semiconductor chip to penetrate the capping layer and the mold layer; and
a second redistribution substrate on the capping layer and electrically connected to the conductive post, wherein:
each of the mold and capping layers comprises an epoxy resin and a first element,
a first concentration of the first element in the mold layer is different from a second concentration of the first element in the capping layer, and
the first element comprises aluminum (Al) or silicon (Si).

13. The semiconductor package of claim 12, wherein the mold layer covers a top surface of the semiconductor chip, and
wherein the capping layer is spaced apart from the semiconductor chip.

14. The semiconductor package of claim 12, wherein the first concentration of the first element in the mold layer is greater than the second concentration of the first element in the capping layer.

15. The semiconductor package of claim 12, wherein the mold layer comprises a first portion, which is on the semiconductor chip and is overlapped with the semiconductor chip in a plan view, and a second portion, which is on a side surface of the semiconductor chip, and
wherein the capping layer is in contact with a top surface of the second portion.

16. The semiconductor package of claim 15, wherein a top surface of the capping layer is coplanar with a top surface of the first portion.

17. The semiconductor package of claim 12, further comprising a metal pattern between the second redistribution substrate and the semiconductor chip,
wherein the metal pattern is in contact with a top surface of the semiconductor chip.

18. The semiconductor package of claim 17, wherein the metal pattern is a plate-shaped pattern.

19. A semiconductor package, comprising:
a first redistribution substrate including first insulating layers and first redistribution patterns at least partially penetrating the first insulating layers;
a semiconductor chip on the first redistribution substrate;
a mold layer on the first redistribution substrate to cover the semiconductor chip;
a capping layer on the mold layer;
a conductive post horizontally spaced apart from the semiconductor chip to penetrate the capping layer and the mold layer;
a second redistribution substrate on the capping layer, the second redistribution substrate comprising second insulating layers and second redistribution patterns at least partially penetrating the second insulating layers; and
an outer coupling terminal on a bottom surface of the first redistribution substrate,
wherein the first redistribution patterns, the conductive post, and the second redistribution patterns are electrically connected to each other, and
wherein a thermal conductivity of the mold layer is higher than a thermal conductivity of the capping layer.

20. The semiconductor package of claim 19, wherein:
each of the mold and capping layers comprises an epoxy resin and a first element,
a first concentration of the first element in the mold layer is different from a second concentration of the first element in the capping layer, and
the first element is aluminum (Al) or silicon (Si).
